(19) United States
(12) Patent Application Publication
(10) Pub. No.: US 2004/0081095 A1
(43) Pub. Date: Apr. 29, 2004

(54) Policing mechanism for resource limited wireless MAC processors

(76) Inventors: Yonghe Liu, Dallas, TX (US); Matthew B. Shoemake, Allen, TX (US)

Correspondence Address: TEXAS INSTRUMENTS INCORPORATED, P O BOX 655474, M/S 3999, DALLAS, TX, 75265

(21) Appl. No.: 10/282,629

(22) Filed: Oct. 29, 2002

(51) Int. Cl. G01R 31/08; H04J 3/14

(52) U.S. Cl. 370/230.1; 370/329

(57) ABSTRACT

A policing mechanism 100 for a resource limited wireless MAC processor. The policing function is enforced at both the host software and embedded firmware. The responsibility of the policer on the host prevents ill behaved flows from flooding the firmware and thus blocking other flows. The policer on the firmware prevents users with bad channels from occupying the channel with low rate transmissions/retransmissions and thus blocking others from transmission.

### BACKGROUND OF THE INVENTION

1. Field of the Invention

This invention relates generally to wireless communication systems, and more particularly, to a policing mechanism for a resource limited wireless MAC processor. The invention is particularly useful and relevant to packet based wireless local area networks such as IEEE 802.11-based networks.

2. Description of the Prior Art

Quality of Service (QoS) provisioning is the process of guaranteeing network resources to a traffic flow, according to the requirements of that traffic flow. Since the network may consist of various resources, providing end-to-end QoS requires interaction and coordination among different parties composing the network. This can happen vertically between two different layers and/or horizontally between the same layers on two different networks.

A typical architecture of a QoS enabled layer is depicted in FIG. 1. The process for providing QoS to a certain flow is detailed below with reference to FIG. 1. A request for a certain amount of resources is first passed to the QoS enabled resource management entity corresponding to a certain layer. Upon receiving the request, the management entity decides whether to reject or accept the request. This decision making process is called “admission control”. In order to perform this functionality, the Admission Control Entity (ACE) 10 may need to monitor the current load on the network and to predict the future requirements. During the admission control process, the ACE 10 may need to negotiate with other ACEs in its lower layer or in other networks through a pre-defined signaling protocol. If the specified requirements cannot be satisfied by all the parties on the path, the ACE 10 may require the upper layer 12 to reduce its requests or the ACE 10 may reject the request.

Once admitted into the system upon agreement of certain resource requirements, the application or upper layer 12 can then send traffic complying with this agreement. Because bandwidth is one of the most important parameters for QoS enabled applications, the network administrator should regulate bandwidth allocation to prevent ill-behaved/greedy flows from violating the agreement that may affect other flows. This functionality is enabled by the “traffic policing” mechanism 14. Traffic conforming to the agreement will pass the traffic policer 14, while non-conforming traffic will be either dropped or buffered.

Once passed through the policer 14, traffic will be scheduled onto the channel or to a lower layer 16 for transmission. The function of the traffic scheduler 18 is to decide the serving order for different packets among different flows. The most common scheduler is First In First Out (FIFO). However, FIFO generally provides no QoS guarantee. Therefore, various schedulers are designed to compensate this. Among these various schedulers, Strict Priority (SP), Weighted Fair Queuing (WFQ), and Earliest Deadline First (EDF) are the best known ones with numerous variants.

The scheme illustrated in FIG. 1 is on a per flow basis generally referred to as Integrated Service (InterServ). Due to the large magnitude of bandwidth available on some of the networks, e.g. core networks, per flow QoS provisioning, even at the finest granularity, may lead to scalability issues. Therefore, to overcome these scalability issues, mechanisms such as Differentiated Service (DiffServ) and Aggregated Signaling are proposed for these high bandwidth networks. However these scalability problems and solutions apply to core networks only. For the 802.11 networks of interest, per flow QoS provisioning is realizable due to the limited available bandwidth.

From the software point of view, a wireless LAN equipment is generally partitioned into host driver and embedded software. The host driver's main functionality, in addition to other necessary controls, is to perform data transferring between the firmware and higher layer residing on the host. The firmware's main functionality, in addition to other necessary controls, is to perform data transferring between the host and the wireless channel. Multiple traffic flows generally are simultaneously being transferred from host to firmware and then onto the wireless medium, or vice versa. It should be noted that limited memory on the firmware and capacity on the wireless medium are shared by all the flows.

In view of the foregoing observations, it is both desirable and advantageous to provide a method of providing a policing function that is enforced at both the host software and embedded firmware. The responsibility of the policer on the host should prevent ill behaved flows from flooding the firmware and thus blocking other flows. The policer on the firmware should prevent users with bad channels from occupying the channel with low rate transmissions/retransmissions and thus blocking others from transmission.

### SUMMARY OF THE INVENTION

The present invention is directed to a policing mechanism for a resource limited wireless MAC processor. The policing function is enforced at both the host software and embedded firmware. The responsibility of the policer on the host prevents ill behaved flows from flooding the firmware and thus blocking other flows. The policer on the firmware prevents users with bad channels from occupying the channel with low rate transmissions/retransmissions and thus blocking others from transmission.

According to one embodiment, a method of policing a resource limited wireless processor comprises the steps of providing a two phase policing mechanism; operating one phase of the policing mechanism to prevent predetermined firmware from being flooded by ill-behaved incoming traffic streams; and operating the other phase of the policing mechanism to isolate good channel stations from bad channel stations on a wireless medium.

### BRIEF DESCRIPTION OF THE DRAWINGS

Other aspects, features and advantages of the present invention will be readily appreciated, as the invention becomes better understood by reference to the following detailed description, when considered in connection with the accompanying drawing figures wherein:

FIG. 1 is a diagram illustrating a typical architecture associated with a QoS enabled layer;

FIG. 2 depicts a two-phase policing mechanism according to one embodiment of the present invention;

FIG. 3 is a flow diagram illustrating a policing process according to one embodiment of the present invention; and

FIG. 4 is a flow diagram illustrating a policing process according to another embodiment of the present invention.

While the above-identified drawing figures set forth particular embodiments, other embodiments of the present invention are also contemplated, as noted in the discussion. In all cases, this disclosure presents illustrated embodiments of the present invention by way of representation and not limitation. Numerous other modifications and embodiments can be devised by those skilled in the art which fall within the scope and spirit of the principles of this invention.

### DETAILED DESCRIPTION OF THE PREFERRED EMBODIMENTS

The particular embodiments of the present invention are better understood by first describing preferred Queue and Memory Management details. Preferred Queue Management is discussed first herein below.

AP Queue Management

For the AP implementation, traffic stream queues should preferably be maintained on the host, whereas priority queues should preferably be maintained by the firmware. This means there may be a larger number of stream queues on the host while only a small number of priority queues on the firmware.

Ideally, the queue management on the host would be dynamic to save memory and increase flexibility. However, this is not mandatory. The queue management on the firmware side may or may not be dynamic. Even if it is not dynamic, the maximum number of queues (16) as specified in the standard IEEE draft (802.11e 3.0) may be easily accommodated on the firmware.

Station Queue Management

For the Station implementation, the host should maintain a queue per traffic stream. The firmware should maintain a queue for each service level.

Ideally, the queue management on the host would be dynamic to save memory and increase flexibility. However, this also is not mandatory. The queue management on the firmware side may or may not be dynamic. Even if it is not dynamic, the maximum number of queues (16) as specified in the standard IEEE draft (802.11e 3.0) may be easily accommodated on the firmware.

It should be noted that per stream queue on the host at a station may be desirable, as multiple streams belonging to the same priority may co-exist. A user may, for example, simultaneously have streaming video and video conferencing. It may be improper to put them in different priorities. Therefore, scheduling needs to be performed on these two streams and hence per stream queue is preferred.

The current draft of IEEE 802.11e does not require data frames to match the TID in the QoS Poll frame. If any future revision requires the TIDs to match, the firmware must maintain a separate queue for each TSpec on the station side. Even if traffic may only exist in the upper eight queues, a station may, for the purpose of sending out traffic fast, still contend for the channel through EDCF access method. The firmware design should not limit this flexibility.

Memory availability for frame buffering on the firmware is limited—often on the order of several KB for most of the devices. Therefore, to avoid any blocking due to out of memory conditions, it may be desirable to statically reserve buffers for higher priority traffic.

Memory Management

Once a frame is scheduled to be transferred to the firmware, the host will insert its descriptor into the array (or link list) shared with the firmware side. This may trigger the transfer process between the host and firmware through DMA engine. Once the frame has been successfully transmitted over the wireless channel, the descriptor in the shared memory can then be freed and ready for use by the host to schedule another frame.

From the host point of view, out-of-order transmission may possibly happen on the firmware side among different priorities. This behavior is desirable and may happen regularly. Therefore, in order to reduce searching complexity for the correct descriptor, a separate descriptor array (or link list) should be maintained.

Further, out-of-order transmissions may happen within the same priority on the firmware as well. A packet, for example, may be intentionally delayed due to policing. Therefore, searching the descriptor list within a priority may be necessary. However, this is expected to be an uncommon phenomena; and computational complexity should not be a concern.

Traffic Policing

Before discussing details of the particular policer embodiments described herein below with reference to FIGS. 2-4, it is noteworthy that policing is basically happening at the AP for QoS provisioning; and as under HCF, the AP grants TXOP for both up- and down-link transmissions over the wireless medium. However, a station may possibly need a policing mechanism to prevent firmware flooding, as stated herein before.

Once a flow has been admitted into the system, the flow should most preferably not deviate from the pre-negotiated QoS parameters. However, the operator has to enforce this commitment using its own traffic policing mechanism to prevent ill-behavior flows from flooding the system. It is also noteworthy that a traffic policing mechanism is often referred to as policer, shaper, and conditioner, among other things.

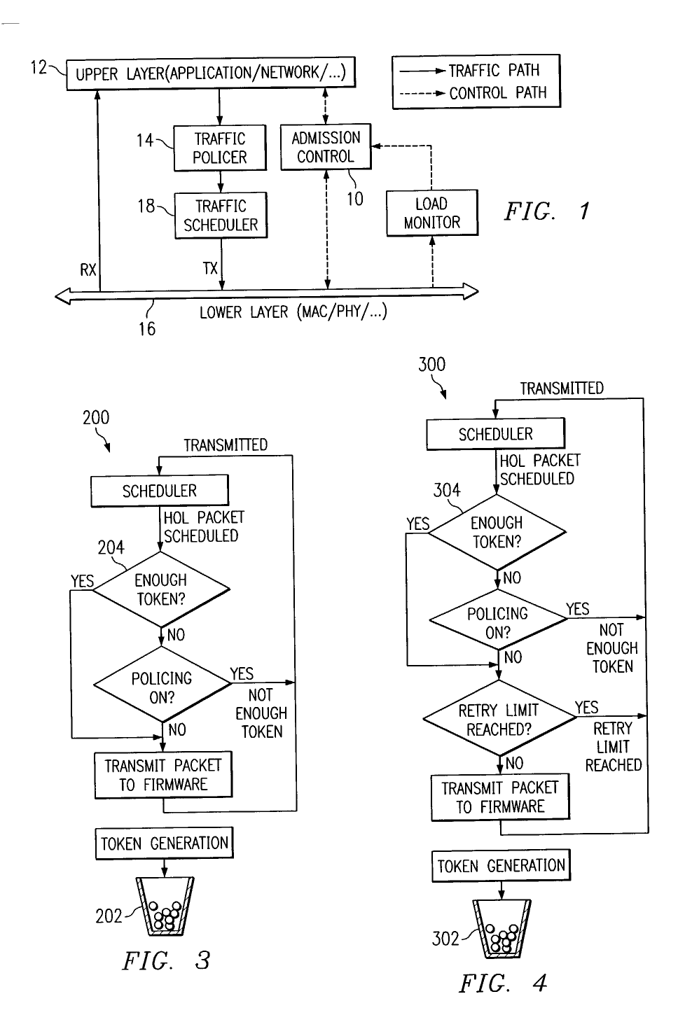

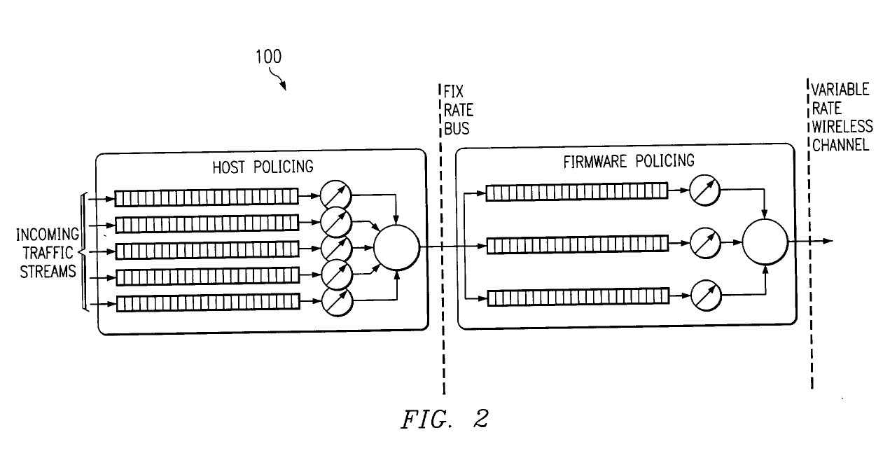

The most popular policer used and that is suitable for use in association with the embodiments described herein below with reference to FIGS. 3 and 4, is token buckets. According to the pre-negotiated rate and burst information of the flow, a token bucket with a certain depth is constantly filled in at a certain rate. Tokens are removed upon transmission of the flow and accumulated while it is idle. The depth of the token bucket limits the size of the burst while the filling in rate regulates the long-term average transmission rate. Two or more buckets can be stacked together for finer control. Two serial token buckets, for example, can regulate both average and peak rates.

However, due to the variation of the wireless channel conditions, a pre-specified bandwidth may possibly become temporarily unavailable. This is due to the time-varying capacity of the wireless channel. For example, due to a bad channel condition, a station transmitting at 1 Mbps (in contrast to the maximum 11 Mbps available under IEEE 802.11b) may consume a much longer time and hence deteriorate other users service as well. Therefore, enforcing time share on the wireless medium is more meaningful than enforcing bandwidth share. This then will ensure that good channel users won't suffer from other users bad channels.

Then HCF contention-free access method provides a handy time-based policing mechanism through TXOP allocation. It is noteworthy however, that bandwidth-based policing is universal and supported by cross-layer and MAC layer signaling; while temporal policing is only a local mechanism at the MAC layer.

Rate and error (hence retransmission) will affect the actual TXOP needed for a specific frame. Immediate information (e.g., frame failure, current transmitting rate, etc) for this is only available at the firmware. Furthermore, immediate TXOP decisions may be necessary to accommodate piggybacked requests. In view of the foregoing, a policing function should most preferably be distributed between firmware and the host, as shown in FIG. 2.

FIG. 2 depicts a two-phase policing mechanism 100 according to one embodiment of the present invention. Traffic is first policed according to the negotiated bandwidth parameters using token buckets from host to firmware. At this stage no channel condition is needed, as the bus rate is almost constant. Traffic passed to the firmware will have to be filtered by a temporal policing mechanism such as discussed herein before. This mechanism will ensure that a bad channel user won't deteriorate service provided to other users.

FIGS. 3 and 4 illustrate the two-phase policing mechanism 100 using Token Generation implemented in respective real systems 200, 300.

Host Policing

The host should most preferably maintain a Token bucket 202, 302 for each stream subject to the policing policy. For downlink data, this will regulate the amount of data going to the firmware; for uplink polling, this will regulate the TXOP allocated for each stream. The TXOP allocated should preferably be based on a normalized rate, e.g. 11 Mbs for 802.11 b and 54 Mbps for 802.11 a. The firmware will make modifications according to the current transmitting rate, which will be discussed in further detail herein below.

The present inventors found providing host side policing to be necessary when the memory on the firmware side is limited. Policing, together with scheduler, on the host side was found to prevent the firmware from being flooded by the non-conforming traffic that may block conforming traffic of other flows.

Firmware Policing

Per stream or per priority Token bucket 202, 302 should most preferably be maintained on the firmware side, dependent on whichever is preferred. When comparing per stream with per priority, Token bucket on the firmware side will provide finer control but also requires more computation and management. Using per stream Token bucket will form a serial Token stack for each stream; using per priority Token bucket on the firmware side (while using a per stream Token bucket on the host side) will result in an aggregated per priority serial Token bucket policing.

Per Stream Policing

The Token bucket of time should most preferably be constantly accumulated at the pre-specified rate till the bucket depth is reached. Before a transmission, re-transmission, or granting of TXOP request for a certain queue, the transmit procedure should consult the Token bucket 204, 304 to see if enough time exists for this particular stream. If not, this stream should be blocked and frame for other queues should be transmitted instead. Upon a successful transmission, the used TXOP should most preferably be deducted from the time bucket.

Per Priority Policing

The Token bucket of time should be constantly accumulated at the pre-specified rate till the bucket depth is reached. It is noteworthy that the rate and depth is the summation for all the streams (uplink or downlink) in the same priority.

Before a transmission, re-transmission, or granting of TXOP request for a certain queue, the transmit procedure should consult the Token bucket 202, 302 to see if enough time exists for this particular priority. If not, this priority should be blocked and frames for other priority queues should be transmitted instead. Upon a successful transmission, the used TXOP should be deducted from the time bucket.

Setting Parameters of Token Buckets

When doing admission control, it is important to remember the possible channel conditions on the wireless channel and over book (provide more than actually needed in the ideal environment) the bandwidth for an individual flow accordingly.

Host Side

It is noteworthy that from host to firmware, the transmission rate can be considered to be constant, such as depicted in FIG. 2. The token bucket 202, 302 on the host should therefore be set exactly according to the pre-negotiated parameters.

Firmware Side

The overbooking should be done on the firmware where errors and rate adaptation really happens. Therefore, the parameters on the firmware side should be larger than that set on the host to allow retransmission of downlink data or granting piggybacking requests for uplink polling. This transformation should be a function of current channel conditions and network load.

Table 1 below summarizes policing associated with the host while Table 2 summarizes policing associated with the firmware.

TABLE 1
Summary for Policing on Host

| Input | | | |
|---|---|---|---|
| From | From | | Output |
| Admission | Scheduler | Action | To Host Scheduler |
| Policing | Scheduling | Token generation and buffering | Current remaining |
| Parameters | Decision | according to the parameters | tokens |
| | | Token deduction according to the | |
| | | Scale parameters to time allocation on | |
| | | on firmware | |

TABLE 2
Summary for Policing on Firmware

| | | | Output |
|---|---|---|---|
| Input | | | To Firmware |
| From Host | From Scheduler | Action | Scheduler |
| Policing | Scheduling | Token generation and buffering | Current remaining |
| Parameters | decision | according to the parameters (Time | TXOP |
| | | based) | |

Disabling Policing Mechanism

Policing is basically only necessary when the network is congested, as stated herein before. The present inventors found that when the network is lightly loaded, the pre-negotiated parameters can be relaxed for better user satisfaction. In other words, the policing mechanism should preferably be disabled upon certain conditions.

Host Side

When the firmware queues are all empty and the wireless medium is idle, the host should most preferably transfer frames to the firmware without regard to the restrictions of host policers.

Firmware Side

When the wireless medium is idle, the firmware should most preferably transfer frames without regard to the restrictions of firmware policers.

Retransmission of Frames

It can be appreciated that retransmission is inevitable over the error prone wireless channel. Retransmission of frames will add additional time over the wireless channel. This is first regulated by the policing mechanism on the firmware, namely that the retransmission, together with transmissions, should not exceed total pre-allocated time such as shown in element 306 in FIG. 4.

However, other retransmission mechanisms should preferably also be employed. The reasons are two-fold. First, solely traffic policing will allow more retransmission chances associated with small data packets. This may be undesirable under bursty error situations. Second, retransmission of frames should be a function of the current load on the host and firmware as well (since the firmware has only limited memory, load on the host plays a more important role). Changing the policing parameters may incur long delays on the desired effect (especially when a per priority policing mechanism is used on the firmware).

Host Side

Host side most preferably should continuously monitor the buffer state and calculate the threshold for retransmission times for the frames on the firmware on a per priority (per queue may be possible but also more costly). This should be indicated to the firmware via the management interface.

Firmware Side

The firmware should preferably set up the retransmission threshold according to the value given by the host side. Upon a failure of transmission/retransmission, the firmware should consult both the policer and this threshold to decide if another retransmission is allowed.

In summary explanation, a policing mechanism for a resource limited wireless MAC processor has been described that can effectively prevent the firmware/wireless medium from being flooded by ill behaved or low priority traffic flows and hence guarantees quality of service to other flows. For some AP products, policing will benefit the overall system quality of service in the whole BSS. For some station products, policing will benefit the local QoS provision if multiple flows presents in the same station.

In view of the above, it can be seen the present invention presents a significant advancement in the art of wireless communication systems. In view of the foregoing descriptions, it should be apparent that the present invention also represents a significant departure from the prior art in construction and operation. However, while particular embodiments of the present invention have been described herein in detail, it is to be understood that various alterations, modifications and substitutions can be made therein without departing in any way from the spirit and scope of the present invention, as defined in the claims which follow.

What is claimed is:

1. A method of policing a resource limited wireless processor, the method comprising the steps of:
providing a two phase policing mechanism;
operating one phase of the policing mechanism to prevent predetermined firmware from being flooded by ill-behaved incoming traffic streams; and
operating the other phase of the policing mechanism to isolate good channel stations from bad channel stations on a wireless medium.

2. The method according to claim 1 wherein the two phase policing mechanism comprises a host policer and a firmware policer.

3. The method according to claim 2 wherein the step of operating one phase of the policing mechanism to prevent predetermined firmware from being flooded by ill-behaved incoming traffic streams comprises operating the host policer to prevent the predetermined firmware from being flooded by the ill-behaved incoming traffic streams.

4. The method according to claim 2 wherein the step of operating the other phase of the policing mechanism to isolate good channel stations from bad channel stations on a wireless medium comprises operating the firmware policer to isolate the god channel stations from the bad channel stations on the wireless medium.

5. The method according to claim 1 wherein the resource limited wireless processor is a MAC processor.

6. The method according to claim 1 wherein the two phase policing mechanism is further operational to provide QoS provisioning to allow access to the wireless medium, and further to allow fair access to the resource on the processor.

7. The method according to claim 1 wherein the step of operating one phase of the policing mechanism to prevent predetermined firmware from being flooded by ill-behaved incoming traffic streams comprises negotiating bandwidth parameters using token buckets from a host to a predetermined processor firmware.

8. The method according to claim 7 further comprising the step of filtering traffic passed to the predetermined processor firmware via a temporal policing mechanism.
